(19) United States
(12) Patent Application Publication
(10) Pub. No.: US 2013/0328180 A1
(43) Pub. Date: Dec. 12, 2013

(54) PACKAGED SEMICONDUCTOR DEVICE WITH AN EXPOSED METAL TOP SURFACE

(71) Applicant: STMicroelectronics S.r.l., Agrate Brianza (MB) (IT)

(72) Inventor: Francesco Salamone, Acireale (IT)

(21) Appl. No.: 13/909,166

(22) Filed: Jun. 4, 2013

(30) Foreign Application Priority Data
Jun. 6, 2012 (IT) VI2012A000136

(51) Int. Cl. H01L 23/34; H01L 21/56

(52) U.S. Cl. CPC H01L 23/34; H01L 21/56
USPC 257/675; 438/122

(57) ABSTRACT

In a manufacturing technique for packaged semiconductor devices, a pre-form of a packaged semiconductor device is formed by a molding process which encapsulates the semiconductor device and its associated heat transfer component in a passivating material presenting a surface. The surface is then processed to at least remove excess passivating material and expose the heat transfer component. The processing may further remove a portion of the heat transfer component. The removal process may, for example, utilize a grinding and/or polishing process. The process may be controlled so as to expose or form a heat transfer surface of desired shape and size.

### PRIORITY CLAIM

This application claims priority from Italian Application for Patent No. V12012A000136 filed Jun. 6, 2012, the disclosure of which is hereby incorporated by reference.

### TECHNICAL FIELD

Generally, the present invention relates to the field of packaging semiconductor devices by using a final passivating molded enclosure.

### BACKGROUND

Immense progress has been made in the field of semiconductor production techniques by steadily reducing the critical dimensions of circuit elements, such as transistors, in integrated circuits. For example, critical dimensions of 30 nm and less have been implemented in highly complex logic circuitry and memory devices, thereby achieving high packing density. Consequently, more and more functions may be integrated into a single semiconductor chip, thereby providing the possibility of forming entire systems on chip so that highly complex electronic circuits may be formed on the basis of a common manufacturing process. Similarly power devices of reduced dimensions at increased output power are increasingly developed, which, possibly in combination with appropriate control circuitry, form smart integrated circuits. Both developments may lead to an increased power generation per unit area on a semiconductor chip, which in turn may require superior heat dissipation capabilities of the corresponding semiconductor device.

It is well established that the communication of an integrated circuit chip, for instance formed on the basis of silicon material, with the periphery, such as a printed circuit board (PCB), is accomplished by incorporating the integrated circuit chip, or two or more integrated circuit chips, in an appropriate casing or package, which thus provides the interface resources for electrically connecting the integrated circuit chip with the wiring system provided on the PCB. Furthermore, the package typically provides for the mechanical and chemical integrity of the integrated circuit chip and thus avoids undue interaction of the environment with the integrated circuit chip. Frequently the packaging of a semiconductor device for forming a packaged semiconductor device is based on an appropriate substrate or carrier material, for instance in the form of a lead frame or any other appropriate structure, to which the one or more semiconductor chips are attached by any appropriate material, such as solder, resin, or any other polymer material. The electrical connections between the integrated circuit chip and the carrier substrate may be formed on the basis of any appropriate contact techniques, such as wire bonding, in which bond wires are connected between corresponding bond pads on the integrated circuit chip and bond areas formed on the carrier substrate. Moreover, an appropriate passivating material is provided so as to enclose the one or more semiconductor chips attached to the carrier substrate, which is typically accomplished by applying a transfer molding process, in which the passivating plastic material is introduced with high-pressure in a low viscous state into a cavity that is formed by the mold and includes the carrier substrate and the one or more semiconductor chips attached thereto.

As discussed above, significant heat may be generated in the integrated circuit chip due to the operation of a plurality of sophisticated transistors or power transistors, thereby also requiring a corresponding dissipation of the heat via the passivating material of the package, which, however, is frequently provided in the form of the plastic material having a relatively low heat conductivity. For this reason, frequently, the passivating material may be provided such that a bottom side of the packaged semiconductor device remains substantially uncovered upon performing the transfer molding process in order to provide a surface portion of superior heat conductivity, which may be brought into direct contact with a corresponding contact pad of the PCB. If required, the respective surface portion may also be used as an electrical contact in order to concurrently reduce the contact resistivity between package and PCB. During the transfer molding process the exposed surface portion of the carrier substrate is realized by urging an exposed bottom surface of the carrier against a plane surface of the mold, while a mold cover is positioned above the carrier substrate and an integrated circuit chip in order to define the mold cavity, which is subsequently filled with the low viscous plastic material. Frequently, an additional foil is positioned between the plane surface of the mold and the carrier substrate in order to reduce leakage between these components, since otherwise significant reworking has to be applied.

In view of even further enhancement in the heat dissipation capabilities of packaged semiconductor devices it has been proposed to also use the top surface thereof as an efficient heat dissipation surface, which typically requires the exposure of an appropriate surface of the component that is in thermal contact with the integrated circuit chip. For example, an appropriate metal component may be incorporated into the packaged semiconductor device so as to provide for superior package internal heat conductivity, while a surface portion thereof may efficiently be coupled to an external heatsink.

FIG. 1a schematically illustrates a perspective view of a packaged semiconductor device 100, which comprises a top surface 100T, which includes a surface portion of superior heat conductivity, for instance provided in the form of a metal surface, such as copper surface. Hence, the metal surface is laterally embedded in a passivating material 101, which provides for the mechanical and chemical characteristics of the packaged semiconductor device 100, as discussed above.

FIG. 1b schematically illustrates a perspective view of the packaged semiconductor device 100, wherein a bottom surface 100B thereof comprises electrical contacts 112 and a metallic surface portion that provides for superior thermal/electrical conductivity, as discussed above.

FIG. 1c schematically illustrates a perspective view of the semiconductor device 100, wherein, for convenience, the passivating material 101 is not shown. The device 100 comprises a carrier substrate, such as the lead frame, and the like, 110, which is appropriately configured so as to provide the metallic portion of the bottom surface 100B of FIG. 1b and which is also appropriately configured to receive an integrated circuit chip or semiconductor device 150, which may comprise any appropriate circuit elements, such as power transistors, sophisticated fast switching transistors, and the like. Furthermore, a heat transfer component 120 is provided, which substantially defines the metallic portion of the top surface 100T as shown in FIG. 1a. The heat transfer component has also the function to electrically connect the semiconductor device 150 to the carrier substrate 110. It should be appreciated that the stacked configuration of the device 100 as shown in FIG. 1 c may comprise more components, which, for convenience, are not shown. For example, any intermediate material in the form of solder material, and the like, so as to attach the semiconductor device 150 to the carrier substrate 110 is not shown. Similarly, any intermediate material providing the connection between the semiconductor device 150 and the heat transfer component 120 is also not shown. Moreover, as previously discussed, in more sophisticated applications the incorporation of two or more integrated circuit chips or semiconductor devices 150 into the packaged device 100 may be required so that in this case the two or more semiconductor devices may be positioned laterally adjacent to each other and/or in a stacked configuration, thereby requiring additional intermediate material layers. Generally, a certain thickness variance of the stacked configuration is unavoidable when assembling the packaged semiconductor device 100. That is, typically the individual components, such as the carrier substrate 110, the semiconductor chip 150 and the component 120 may have a certain thickness tolerance due to their own nature and manufacturing process. In this case, the thickness variance of the stacked configuration is the arithmetical sum of the variances of each element which compose it. For example, for a typical stacked configuration composed as show in FIG. 1c (the substrate 110, the semiconductor chip 150, the component 120, the solder between the substrate 110 and the chip 150 and the solder between the chip 150 and the component 120) the packaged semiconductor device 100 may be provided, prior to the transfer molding process, with a tolerance of approximately ±80 μm. Furthermore, the degree of parallelism between the component 120 and the substrate 110 that is the chief double upon configuring the stacked configuration of the device 100 may additionally contribute to a pronounced variance of the total height of the device 100 across the entire surface area. Consequently, by using a conventional transfer molding system, upon forming the packaged semiconductor device 100 as for instance shown in FIGS. 1a and 1b typically significant yield losses may be observed, for instance due to catastrophic failures caused by undue mechanical forces acting on the semiconductor chip 150 during the transfer molding process, while in other cases significant amounts of molds material may still be present on the top surface 100T, thereby significantly reducing the heat transfer efficiency thereof and/or requiring substantial reworking, which in turn is not compatible with volume production techniques. For example, a variation of the above described to ensure molding process based on appropriate for those for obtaining the required ceiling effect during the transfer molding process may be applied, as will be described with reference to FIGS. 1d to 1g.

FIG. 1d schematically illustrates a cross-sectional view of the device 100 during a transfer molding process 160, in which the components 110, 150 and 120 in combination with any intermediate material layers (not shown) are to be embedded into a passivating material while attempting to retain exposed metallic surface areas, as for instance shown in FIGS. 1a and 1b. To this end, a foil 161, such as an adhesive foil having a thickness of approximately 40 μm may be used to position the stacked configuration of the device 100 on a plane surface (not shown) of the mold assembly. As discussed above, the foil 161 may result in reduced leakage of mold material during the actual molding process. In an attempt to further accommodate the pronounced tolerances of the stacked device 100, for instance as indicated by the dashed lines, a further foil 162 may be provided in combination with a mold cover 163, wherein the foil 162 may be provided with a thickness of approximately 50 to 100 μm.

FIG. 1e schematically illustrates the mold cover 163 (which in some cases could have a package thickness compensation system obtained by adding a spring between the cap and the upper side of the mold chase) and the foil 162 that adheres to the cover 163 in a configuration, in which a cavity 163C is defined. Consequently, in this configuration the mold cover 163 may be lowered and may thus be positioned above the device 100.

FIG. 1f schematically illustrates a cross-sectional view of the molding process 160, in which the molding chase is closed by positioning the cover 163 above the device 100. In this configuration the passivating material 101 is introduced with high pressure into the resulting cavity so as to reliably fill the remaining volume without any gas bubbles, and the like. As discussed above, the foils 161 and 162 are provided so as to a sufficiently seal the respective cavity. As discussed above, however, the pronounced variance of the height and parallelism of the device 100 (cf FIG. 1d) may nevertheless require a significant pressure to be applied on the device 100, which in turn may result in significant damage of the semiconductor device 150, while an appropriate reduction of the vertical mechanical forces during the molding process 160 may nevertheless cause undue leakage of the material 101.

FIG. 1g schematically illustrates the packaged device 170 upon lifting the mold cover 163 and the foil 162 in order to obtain the packaged device laterally enclosed by the material 101. It turns out, however, that the top surface 100T may still comprise plastic material and/or function of failure of the device 100 may be observed, thereby contributing to increased yield loss. Moreover, it turns out that the molding process 160 on the basis of the two foils 161 and 162 may significantly contribute to increased production costs, which, in combination with high yield loss and/or increased reworking efforts due to residues of plastic material on the top surface 100T, may render this approach less than desirable. There is a need in the art to provide process techniques and devices while avoiding or at least reducing the effects of one or more of the problems identified above.

### SUMMARY

Basically, the present disclosure contemplates manufacturing techniques and respective devices and systems, in which a top surface of the packaged semiconductor device may have a surface portion of superior heat conductivity, which may be accomplished by exposing or forming at least partially a corresponding surface area of the heat transfer component after enclosing the heat transfer component at least partially in a passivating material. In this manner, any tolerances with respect to the overall height of the stacked configuration and/or the parallelism of internal components of the stacked configuration may efficiently be taken into consideration, while still enabling the application of cast efficient volume production techniques.

In one illustrative aspects of the present disclosure a method comprises forming a pre-form of a packaged semiconductor device, wherein the pre-form package embeds the semiconductor device attached to a substrate and a heat transfer component thermally coupled to the semiconductor device. The method further comprises forming the packaged semiconductor device from the pre-form by applying a material removal process to the surface so as to form an exposed surface portion from the heat transfer component.

Hence, according to the disclosed method that pre-form of the packaged semiconductor device may be provided so as to have any appropriate surface configuration with respect to covering the heat transfer component with the passivating material, while the exposure of a surface portion thereof is accomplished in a subsequent independent process by removing an appropriate amount of material. Consequently, upon actually forming the exposed surface portion of the heat transfer component any tolerances or a certain degree of non-parallelism of the components of the packaged semiconductor device do not negatively affect the resulting exposed surface portion. In particular, well-established material removal processes may be applied, which are compatible with volume production techniques. Similarly, the pre-form of the packaged semiconductor device may be manufactured on the basis of any desired process strategy, for instance by applying it transfer molding process, without being significantly affected by the tolerances of the stacked configuration.

In a further illustrative embodiment the step of applying a material removal process comprises performing at least one of a grinding process and a polishing process on the surface. In this manner, the material removal may be accomplished on the basis of processes, which are well established in the art of semiconductor production and packaging of semiconductor devices, wherein in particular the grinding and/or a polishing process may per se result in a substantially even, smooth and parallel top surface of the packaged semiconductor device, irrespective of the tolerances of the stacked configuration of the pre-form of the packaged semiconductor device.

In a further illustrative embodiment the step of forming the pre-form of a packaged semiconductor device comprises positioning the substrate with the semiconductor device and the heat transfer component in a mold assembly and filling the mold assembly with a curable mold material so as to at least partially cover the heat transfer component. Hence, well-established molding processes may be applied for forming the pre-form, wherein any tolerances and non-parallelism of the stacked configuration may readily be taken into account by the molding process. That is, the molding process may generally be designed such that any practical range of tolerances and non-parallelism may be covered, for instance by selecting an appropriate height of the molds cavity, so that, for instance, undue mechanical forces acting on the semiconductor device may reliably be avoided.

Preferably, the mold assembly is filled so as to completely cover the heat transfer component. Hence, the configuration of the mold assembly may appropriately be selected such that the mold material reliably covers the heat transfer component and thus forms the top surface of the pre-form of the packaged semiconductor device so as to provide a top surface entirely form of the mold material.

In one illustrative embodiment the heat transfer component comprises a metal material. In this manner, the package internal heat distribution as well as the heat dissipation across the exposed surface portion of the heat transfer component impart superior performance to the packaged semiconductor device.

In a further illustrative embodiment the step of forming the pre-form further comprises providing the heat transfer component with a heat transfer surface and aligning the heat to transfer surface with respect to the surface. In this case, a well-defined surface area of the heat transfer component may be provided so as to be aligned with respect to the surface to be formed from the passivating material. The process of aligning the heat transfer surface may be performed in compliance with well-established process techniques, wherein the actually achieved degree of alignment may substantially not affect the final size and shape of the heat transfer surface that is finally exposed in the top surface of the packaged semiconductor device. That is, the heat transfer component and in particular the surface thereof may be selected such that upon grinding and/or polishing the surface of the pre-form the resulting exposed surface area of the heat structure component has the desired size and shape by simply continuing the polishing/grinding process. For example, if the thickness of the passivating material above the surface area of the heat transfer component varies due to process related non-uniformities, and the like, the material removal process may be continued so as to completely expose the surface area of the heat transfer component, while in areas of reduced thickness of the passivating material increasingly the material of the heat transfer component may be removed. In this manner a high degree of parallelism and in total superior planarity of the resulting surface of the packaged semiconductor device may be accomplished.

In one illustrative method disclosed therein the surface is one of a top surface and a bottom surface of the packaged semiconductor device. It should be appreciated that, although the above described process technique may be applied to any surface area of the packaged semiconductor device, it is highly advantageous to apply the process to the bottom and/or top surface, since typically here electrical connections and heat dissipation capabilities are required.

According to a further illustrative aspect of the present disclosure there is provided a packaged semiconductor device. The packaged semiconductor device comprises a semiconductor device attached to a substrate and electrically connected to one or more contact elements formed at a bottom surface of the packed semiconductor device. Furthermore, the packaged semiconductor device comprises a heat transfer component thermally coupled to the semiconductor device, wherein the heat transfer component includes a heat transfer surface. Moreover, the packaged semiconductor device comprises a passivation material in contact with the semiconductor device, the substrate and the heat transfer component. Additionally, the packaged semiconductor device comprises a top surface formed by the heat transfer surface and a surface portion of the passivation material, wherein the top surface is at least one of a ground and a polished surface.

Consequently, the packaged semiconductor device comprises a superior surface characteristics in terms of heat dissipation capability, since due to the ground or polished surface configuration any residues of plastic material may be avoided, which are frequently encountered in conventional packaged semiconductor devices. Furthermore, the ground and/or polished surface configuration may allow a further contact material to be applied on the exposed surface area, for instance in the form of solder material, conductive recursive material, and the like.

In a further illustrative embodiment at least the heat transfer surface is comprised of metal. In this manner, superior electrical and thermal conductivity is obtained, as is also discussed above.

In illustrative embodiments the metal comprises at least one of aluminum and copper, thereby providing materials that are well-established in the semiconductor industry and that allow an efficient further processing of the packaged semiconductor device, for instance with respect to incorporation in a more complex electronic system, connection to a heat sink, and the like.

In a further illustrative embodiment the packaged semiconductor device further comprises a metal containing surface portion provided in the bottom surface. In this manner, superior electrical and/or thermal conductivity at both the top surface and the bottom surface areas provided.

In one illustrative embodiment the passivation material is a plastic material, thereby providing for a high degree of compatibility with conventional packaging techniques.

In a further illustrative embodiment the heat transfer surface is laterally embedded in the passivation material, wherein a height difference between the heat transfer surface and the passivation material in the top surface is 10 μm and less. Hence, an appropriate degree of planarity is provided in the top surface of the packaged semiconductor device, thereby allowing superior mechanical contact to other components, such as a heat sink, and the like. In some illustrative embodiments, the height difference is 5 μm and less, wherein also an average roughness of the metallic and the plastic surface areas is 5 μm or less. Hence, in addition to a high degree of planarity appropriate surface roughness characteristics may be provided in order to enable an efficient further processing of the packaged semiconductor device.

According to a further illustrative aspect of the present disclosure an electronic system comprises a printed circuit board and a packaged semiconductor device. The packaged semiconductor device may have features and characteristics as are also described above and as will be described later on in more detail when referring to the detailed description. The packaged semiconductor device is attached with its bottom surface to the printed circuit board and is attached to a heat sink via its heat transfer surface.

### BRIEF DESCRIPTION OF THE DRAWINGS

FIGS. 1a to 1c schematically illustrate perspective views of a packaged semiconductor device, in which a top surface and a bottom surface thereof should be provided with a metallic surface area in order to enhanced heat dissipation capabilities,

FIGS. 1d to 1g schematically illustrate cross-sectional views of a molding process for forming a packaged semiconductor device on the basis of a conventional molding process using two foils in an attempt to expose a metallic top surface area,

FIGS. 2a to 2c schematically illustrates cross-sectional views of a packaged semiconductor device, wherein the heat transfer surface is exposed at a top surface of the packaged semiconductor device on the basis of a grinding and/or a polishing process according to illustrative embodiments and

FIG. 2d schematically illustrates a cross-sectional view of an electronic system comprising a packaged semiconductor device according to still further illustrative embodiments.

### DETAILED DESCRIPTION OF THE DRAWINGS

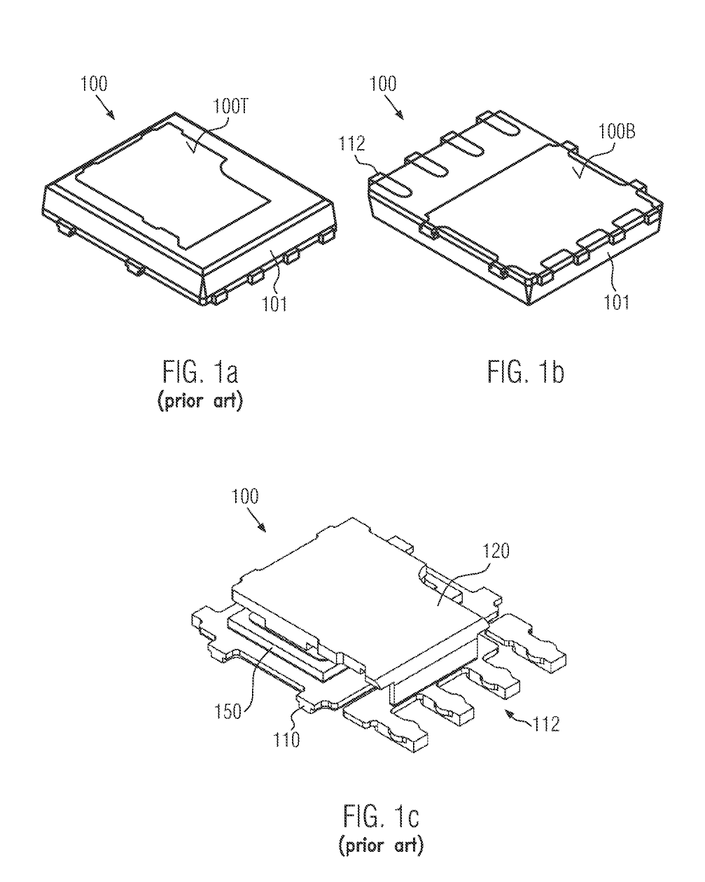

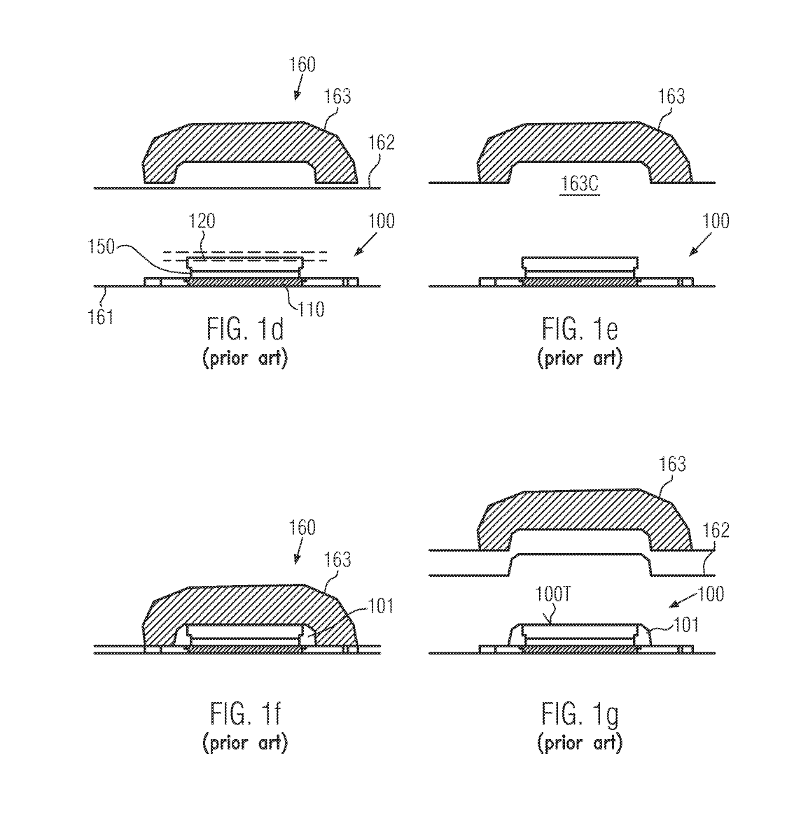

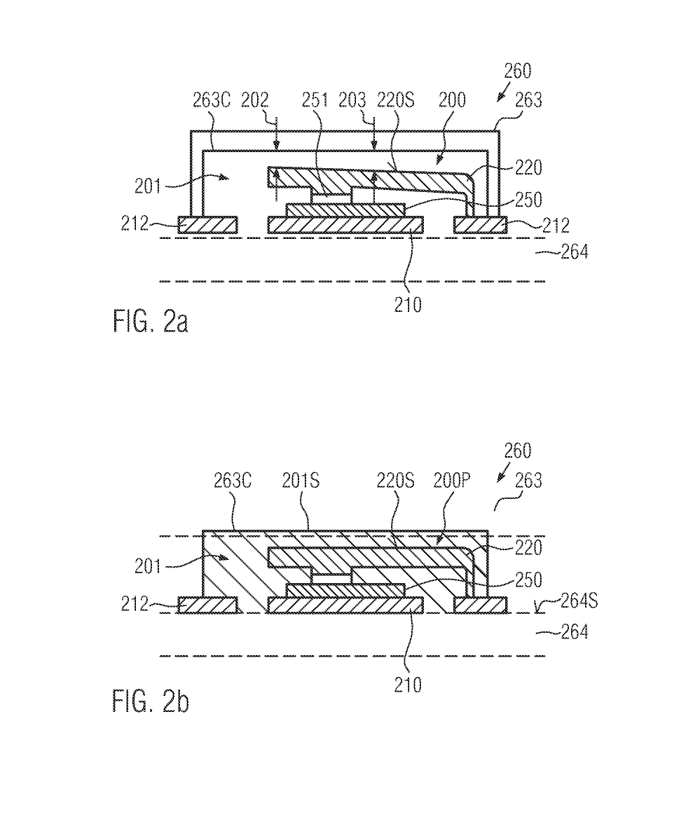

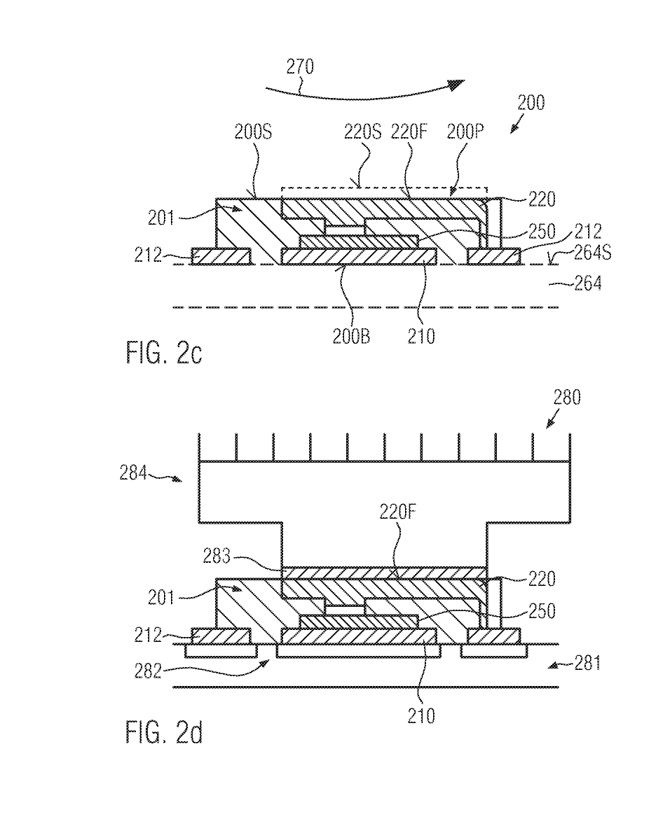

With reference to FIGS. 2a to 2d further illustrative embodiments of the present disclosure will now be described in more detail, wherein also reference may be made to FIGS. 1a to 1e if required.

FIG. 2a schematically illustrates a cross-sectional view of a packaged semiconductor device 200 in an early manufacturing stage, in which a molding process 260 is to be applied so as to embed components of the device 200 in an appropriate passivating material. The packaged semiconductor device 200 may comprise a carrier substrate 210, for instance a lead frame, and the like, so as to receive a semiconductor device 250, which may be provided in the form of one or more semiconductor chips having incorporated therein any appropriate type of electronic circuitry so as to comply with the functional requirements of the device 200. The semiconductor device 250 may be attached to a portion of the substrate 210 by using any appropriate intermediate material (not shown), such as solder material, and the like thereby establishing a mechanical and thermal coupling between the components 250 and 210. It should be appreciated that the substrate 210 and the semiconductor device 250 may have any appropriate lateral size and shape as required for establishing the required electrical connections, as is also discussed above. For example, electrical contact elements 212 may be provided as a part of the substrate 210 or as separate components, depending on the overall configuration of the substrate 210. For example, the substrate 210 may be provided as an appropriately configured lead frame, as a carrier substrate having formed thereon a conductor structure formed by plating techniques, and the like. The heat transfer component 220 has also the function to electrically connect the semiconductor device 250 and the electrical contact 212. Furthermore, electrical connections between the semiconductor device 250 and the substrate 210, i.e. the electrical contact 212, may be provided on the basis of any appropriate connection technique, such as wire bonding, solder bumps, solder balls, and the like. For convenience, any such electrical connections are not shown in FIG. 2a.

Furthermore, the device 200 comprises a heat transfer component 220, which is attached to the semiconductor device 250 on the basis of any appropriate mechanism, schematically indicated as 251, such as an adhesive material, a solder material, and the like in order to achieve a desired superior thermal and electrical coupling between the component 220 and the semiconductor device 250. For example, the component 220 may be coupled to a corresponding surface portion of the device 250, below which an area of increased heat generation may be positioned. In other cases, the component 220 may be coupled to the entire top surface of the semiconductor device 250, if considered appropriate. Furthermore, it should be appreciated that two or more semiconductor devices 250 may be provided in the device 200, depending on the overall complexity and the design requirements. As also discussed above with reference to the packaged semiconductor device 100, the device 200 may require superior heat dissipation capabilities, which may be provided by exposing at least a portion of a top surface 220S of the component 220.

As discussed above, depending on the overall complexity of the configuration of the device 200 a certain tolerance of the total height of the device 200 is to be taken into consideration, which may be several tens of micrometers and more, while also the degree of parallelism may depend on the tolerances of components and manufacturing processes upon forming the device 200 in a stage as shown in FIG. 2a. For example, as indicated in FIG. 2a a certain degree of non-parallelism may have been introduced and may reflect any tolerances in the fabrication of the individual components and the process of assembling the various components of the device 200. For example, when covering the device 200 by a component 263 of the mold assembly, which defines a mold cavity 263C, the distance between the surface 220S and the mold cover 263 may vary according to the actual total height and the degree of parallelism. For example, due to a certain non-parallelism the distance 202 may be less than a distance 203, wherein both values may vary between different semiconductor devices 200, while also a certain degree of variation of the molding process 260 may contribute to the resulting gap formed above the surface 220S. In some illustrative embodiments, the mold assembly and in particular the size and shape of the mold cover 263 are selected such that any practical manufacturing tolerances of the device 200 and of the process 260 may be accommodated so as to still provide a gap between the cover 263 and the surface 220S. To this end, corresponding data with respect to any reasonable tolerances of the device 200 and the molding process 260 may be obtained, for instance as indicated above in the context of the packaged semiconductor device 100, in order to determine an appropriate design of the mold cover 263 so as to reliably retain a gap between the surface 220S and the cover 263. In this manner, it is ensured that a portion of a passivating material 201, which is to be inserted into the 263C during the molding process 260 is provided above the surface 220S in order to form a preliminary surface of the device 200.

Consequently, upon providing the device 200 in a stacked configuration, as for instance shown in FIG. 2a, the molding process 260 may be applied, for instance by positioning the device 200 on an appropriate carrier 264, which may additionally be equipped with an appropriate foil (not shown), as for instance discussed above with reference to FIGS. 1d to 1e in order to provide for superior leakage behavior during the molding process 260, when introducing the material 201 in a low viscous state assets a moderately high pressure. In other cases, the surface of the carrier material 264 is appropriately configured so as to provide for sufficient sealing behavior during the process 260. Moreover, in some illustrative embodiments the carrier 264 may be appropriately configured so as to allow the further processing of the device 200 after the molding process 260 without requiring the removal of the device 200 from the carrier 264 when further processing the device 200.

After closing the mold assembly and thus defining the cavity 263C the material 201 is introduced and subsequently cured, possibly including a further process step after the removal of the mold assembly, a preliminary state of the semiconductor 200 may be obtained, which is also referred to herein as a pre-form.

FIG. 2b schematically illustrates a cross-sectional view of the device after the above described molding process and after the removal of the mold assembly, thereby providing a pre-form 200P, wherein the components 220, 250 and 210 are at least laterally embedded in the cured passivating material 201. Furthermore, this material also forms a surface 201S of the pre-form 200P, irrespective of any tolerances with respect to total height of the internal components of the pre-form 200P or parallelism of the various components, as discussed above. It should be appreciated that in other illustrative embodiments (not shown) the heat transfer surface 220S may not necessarily be completely covered by the material 201, since a substantially even and parallel surface may be established in a later manufacturing stage by concurrently removing material of the component 220 and 201 during a corresponding material removal process. In this manner, increasingly additional portions of the surface 220S may be exposed or formed, as long as the component 220 has a sufficient thickness so as to still enable the provision of a surface area having the desired shape and size compatible to the shape and size of the initial heat transfer surface 220S.

As discussed above, it should be appreciated that depending on the tolerances of the molding process 260 the surface 201S may be more or less parallel to a surface 264S of the carrier 264, while on the other hand, the surface 220S may have a certain degree of tilt with respect to the surface 264S, since it is typically very difficult to provide for a high degree of parallelism upon forming the stacked configuration of the device 200P, as is also discussed above.

FIG. 2c schematically illustrates a cross-sectional view of the device 200 in its final configuration, which may be accomplished upon applying the material removal process 270 to the pre-form 200P as shown in FIG. 2b. To this end, the device 200P of FIG. 2b may be processed in any appropriate process tool so as to perform the material removal process 270, wherein in some cases, as discussed above, the pre-form 200P may remain positioned on the carrier 264. In some illustrative embodiments, the removal process 270 may comprise at least a grinding process, possibly in combination with a polishing process, during which increasingly a portion of the material 201 is removed. Depending on the degree of coverage of the heat transfer component 220 and depending on the degree of non-parallelism of the surface 220S also material of the component 220 may increasingly be removed, thereby finally forming or exposing a surface 220F of the component 220, which may substantially correspond in size and shape to the initial surface 220S, except for minor variations which may be caused by a slight inclination, and the like, as discussed above. Consequently, during the removal process 270 a top surface of the packaged device 200 may be formed, in which the exposed surface 220F of the heat transfer component 220 is laterally enclosed by the material 201, wherein a possible step height between the material 201 and of the surface 220F is substantially determined by the characteristics of the corresponding removal process. For example, well established process recipes for removing plastic material in the presence of metal material, such as copper, aluminum, and the like, may be applied in process tools, such as an automatic surface grinding tool (for instance DAG810 supplied from DISCO CORPORATION), in order to form or expose the surface 220F, wherein the resulting surface roughness and any height differences within the top surface may be 10 μm or less, for instance 5 μm or less. It should be appreciated that a polishing process may typically result in an even further reduced overall surface roughness, thereby providing a superior surface quality, if required. Furthermore, the parallelism of a top surface 200S and bottom surface 200B of the device 200 may also be adjusted during the process 270, since typically areas of increased height may preferably be removed compared to areas of reduced height across the device 200. Hence, the resulting surface quality and the degree of parallelism may be adjusted on the basis of the characteristics of the removal process 270, wherein well-established process tools and process techniques may be applied, which are also compatible with volume production techniques. In particular the surface 220F of the heat transfer component 220 has an appropriate surface quality that efficiently allows the further processing of this surface, for instance with respect to apply a plating process, a solder process, and the like. In this manner, the exposed surface 220F imparts superior thermal conductivity and thus heat dissipation capabilities to the packaged semiconductor device 200. Furthermore, if required, the surface 220F may also be used as an electrical contact region of the device 200, depending on the overall configuration and internal connection to the semiconductor device 250.

Thereafter, the packaged semiconductor device 200 may be removed from any carrier material and may be further processed in accordance with the overall device and process requirements.

FIG. 2d schematically illustrates a cross-sectional view of an electronic system 280, which comprises an appropriate substrate 281, for instance in the form of a PCB including any wiring system so as to connect to the packaged semiconductor device 200 and to any other components (not shown) provided in the system 280. For convenience, a contact structure 282 is illustrated only, while any other metal traces, and the like, of the PCB 281 are not shown. The contact structure 282 may thus represent a complementary structure with respect to a corresponding contact regime provided in the packaged semiconductor device 200, for instance in the form of the component 210, whose bottom surface may still be exposed, if required. For example, the bottom surface 200B (cf FIG. 2c) may comprise exposed surface areas of the component 210, as for instance also shown in FIG. 1b when referring to the packaged semiconductor device 100. Consequently, an appropriate electrical and thermal connection of the packaged semiconductor device 200 to the PCB 281 may be accomplished, for instance by any appropriate contact technology. Furthermore, the system 280 may comprise a further component 284, such as the heat sink, and the like, which may connect to at least a portion of the exposed surface 220F in order to provide superior thermal coupling between the component 220 and the component 284. To this end, any intermediate material 283, such as solder, adhesive material with superior heat conductivity, and the like may be provided so as to couple the components 284 and 220. If required, the component 284 may also provide for electrical connection to the packaged semiconductor device 200, if required.

As a result, the present disclosure provides packaged semiconductor devices, electronic systems and manufacturing techniques, in which a surface of a packaged semiconductor device may be formed so as to expose a heat transfer surface of a corresponding component, substantially without depending on any tolerances of dimensions of the packaged semiconductor device prior to providing the passivating material thereof. This may be accomplished by forming a pre-form of the packaged semiconductor device so as to be tolerant with respect to component and process tolerances, followed by the removal process, such as a polishing and/or grinding process in order to remove a sacrificial portion of the passivating material in order to expose a desired portion of the heat transfer component.

What is claimed is:

1. A method, comprising:
forming a pre-form of a packaged semiconductor device so as to have a surface formed at least partially from a passivation material, said pre-form comprising the semiconductor device attached to a substrate and a heat transfer component thermally and electrically coupled to said semiconductor device; and
forming said packaged semiconductor device from said pre-form by applying a material removal process to said surface so as to form an exposed surface portion from said heat transfer component.

2. The method of claim 1, wherein applying the material removal process comprises performing at least one of a grinding process and a polishing process on said surface.

3. The method of claims 1, wherein forming said pre-form of a packaged semiconductor device comprises positioning said substrate with said semiconductor device and said heat transfer component in a mold assembly and filling said mold assembly with a curable mold material so as to at least partially cover said heat transfer component.

4. The method of claim 3, wherein said mold assembly is filled so as to completely cover said heat transfer component.

5. The method of claim 1, wherein said heat transfer component comprises a metal material.

6. The method of claim 3, wherein forming said pre-form further comprises providing said heat transfer component with a heat transfer surface and aligning said heat transfer surface with respect to said surface.

7. The method of claim 6, wherein said material removal process is continued so as to completely expose said heat transfer surface.

8. The method of claim 7, wherein said surface is one of a top surface and a bottom surface of said packaged semiconductor device.

9. A packaged semiconductor device, comprising:
a semiconductor device attached to a substrate and electrically connected to one or more contact elements formed at a bottom surface of said packed semiconductor device;
a heat transfer component thermally coupled to said semiconductor device, said heat transfer component having a heat transfer surface;
a passivation material in contact with said semiconductor device, said substrate and said heat transfer component; and
a top surface formed by said heat transfer surface and a surface portion of said passivation material, said top surface being at least one of a ground surface and a polished surface.

10. The packaged semiconductor device of claim 9, wherein at least said heat transfer surface is comprised of metal.

11. The packaged semiconductor device of claim 10, wherein said metal comprises at least one of aluminum and copper.

12. The packaged semiconductor device claim 9, further comprising a metal containing surface portion provided in said bottom surface.

13. The packaged semiconductor device of claim 9, wherein said passivation material is a plastic material.

14. The packaged semiconductor device of claim 9, wherein said heat transfer surface is laterally embedded in said passivation material with a height difference between said heat transfer surface and said passivation material in said top surface is 10 μm and less.

15. The packaged semiconductor device of claim 9, further comprising a heat sink attached to the heat transfer surface.

16. A method, comprising:
encapsulating a semiconductor device and heat transfer component thermally coupled to said semiconductor device within a passivating material having a top surface; and
applying a material removal process to said top surface so as to form an exposed surface portion comprising a passivating material surface surrounding a heat transfer surface formed by the heat transfer component.

17. The method of claim 16, wherein applying the material removal process comprises performing at least one of a grinding or polishing process to said top surface so as to at least remove a portion of the passivating material to define the exposed surface portion and expose the heat transfer component.

18. The method of claim 17, wherein the material removal process further removes a portion of the heat transfer component to define the exposed surface portion.

19. The method of claim 16, wherein encapsulating the semiconductor device and heat transfer component fully covers the heat transfer component with the passivating material.

20. The method of claim 16, wherein said heat transfer component comprises a metal material.
